(19) United States
(12) Patent Application Publication
(10) Pub. No.: US 2023/0166344 A1
(43) Pub. Date: Jun. 1, 2023

(54) SOLDERING COMPONENT

(71) Applicant: TING-JUI WANG, New Taipei City (TW)

(72) Inventor: TING-JUI WANG, New Taipei City (TW)

(21) Appl. No.: 18/104,306

(22) Filed: Feb. 1, 2023

Related U.S. Application Data
(62) Division of application No. 17/530,473, filed on Nov. 19, 2021.

(51) Int. Cl. B23K 1/002; B23K 1/00; B23K 3/02; B23K 3/08

(52) U.S. Cl. CPC B23K 1/002; B23K 1/0008; B23K 3/08; B23K 3/025; B23K 2103/00

(57) ABSTRACT

The disclosure provides a soldering component and a method of assembling a soldering component to objects, the soldering component comprises a body part and an assembling part, the assembling part is for combining to the object, the body part has a snap-fit part, the snap-fit part has an elastic retracting space, and the elastic retracting space can elastically retract two or more fastening parts, so that each fastening part fastens into another object, and the soldering component has a solderable surface for soldering to an assembling part of the object, the assembling part of the object is preset with a tin soldering layer, which is heated and soldered the soldering component and the assembling part of the object.

### CROSS-REFERENCE TO RELATED APPLICATION

This application is a divisional patent application of U.S. Application No. 17/530,473 filed on Nov. 19, 2021, the entire contents of which are hereby incorporated by reference for which priority is claimed under 35 U.S.C. § 121.

### BACKGROUND OF THE INVENTION

### 1. Field of the Invention

The present disclosure relates to a soldering component and a method of assembling a soldering component to an object, and in particular to a soldering component and a method of assembling a soldering component to an object, which can complete the fastening or unfastening of another object, and achieve the purpose of repeated and quick fastening or unfastening.

### 2. Description of the Related Art

Generally, when at least one object is combined, it is usually locked with screws as a combination of the object.

Although the above method can fixedly combine at least one object, it cannot be easily separated after the combination.

### BRIEF SUMMARY OF THE INVENTION

Based on at least one embodiment of the present disclosure, the disclosure provides a soldering component and a method of assembling a soldering component to an object, which can complete the fastening or unfastening of another object, and achieve the purpose of repeated and quick fastening or unfastening.

To achieve the above objective, the present disclosure provides a soldering component, comprising: a body part and an assembling part, the body part has a snap-fit part, and the soldering component has a solderable surface for combining to an obj ect.

The disclosure further provides a soldering component, comprising: a body part and an assembling part, the body part has a snap-fit part, and the soldering component is used to be stored in a carrier, and picked up by a tool, after matched with an assembly position of the object by a matching device, the soldering component is placed at the assembly position by the tool for combining to the object.

The disclosure further provides a soldering component, comprising: a body part and an assembling part, the assembling part is for combining to the object, the body part has a snap-fit part, the snap-fit part has an elastic retracting space, and the elastic retracting space can elastically retract two or more fastening parts, so that each fastening part fastens into another object.

The disclosure further provides a soldering component, comprising: a body part, an assembling part and a snap-fit part, the soldering component has a solderable surface for soldering to an assembling part of the object, the assembling part of the object is preset with a tin soldering layer, which is heated and soldered the soldering component and the assembling part of the object.

The disclosure further provides a soldering component, comprising: a body part, an assembling part and a snap-fit part, the soldering component has a solderable surface for soldering to an assembling part of the object, the assembling part of the object is preset with a tin soldering layer, which is heated and soldered the soldering component and the assembling part of the object, and a non-solderable layer of the object is below the assembling part of the object.

The disclosure further provides a soldering component, comprising: a body part, an assembling part and a snap-fit part, the soldering component has a solderable surface for soldering to an assembling part of the object, the assembling part of the object is preset with a tin soldering layer, which is heated and soldered the soldering component and the assembling part of the object, the soldering component is first preset in the carrier, and the soldering component is picked by the tool, and after matched with the assembly position of the object by the matching device, the soldering component is placed at the assembly position by the tool for combining with the object.

The disclosure further provides a soldering component, comprising: a body part and an assembling part, the assembling part is for combining to the object, the body part has a snap-fit part, the snap-fit part has an elastic retracting space, and the elastic retracting space can elastically retract two or more fastening parts, so that each fastening part fastens into another object, and the soldering component has a solderable surface for soldering to an assembling part of the object, the assembling part of the object is preset with a tin soldering layer, which is heated and soldered the soldering component and the assembling part of the object, the soldering component is first preset in the carrier, and the soldering component is picked by the tool, and after matched with the assembly position of the object by the matching device, the soldering component is placed at the assembly position by the tool for combining with the object.

The disclosure further provides a soldering component, comprising: a body part and an assembling part, the assembling part is for combining to the object, the body part has a snap-fit part, the snap-fit part has an elastic retracting space, and the elastic retracting space can elastically retract two or more fastening parts, so that each fastening part fastens into another object, and the soldering component has a solderable surface for soldering to an assembling part of the object, the assembling part of the object is preset with a tin soldering layer, which is heated and soldered the soldering component and the assembling part of the object.

The disclosure further provides a soldering component, comprising: a body part and an assembling part, the assembling part is for combining to the object, the body part has a snap-fit part, the snap-fit part has an elastic retracting space, and the elastic retracting space can elastically retract two or more fastening parts, so that each fastening part fastens into another object, and the soldering component is first preset in the carrier, and the soldering component is picked by the tool, and after matched with the assembly position of the object by the matching device, the soldering component is placed at the assembly position by the tool for combining with the object.

The disclosure further provides a soldering component, comprising: a body part and an assembling part, the assembling part is for combining to the object, the body part has a snap-fit part, the snap-fit part has an elastic retracting space, so that the fastening parts fasten into another object, and the soldering component is first preset in the carrier, and the soldering component is picked by the tool, and after matched with the assembly position of the object by the matching device, the soldering component is placed at the assembly position by the tool for combining with the object.

The disclosure further provides a soldering component, comprising: a body part and an assembling part, the assembling part is for combining to the object, the body part has a snap-fit part, the snap-fit part has an elastic retracting space, so that the fastening parts fasten into another object, and the soldering component has a solderable surface for soldering to an assembling part of the object, the assembling part of the object is preset with a tin soldering layer, which is heated and soldered the soldering component and the assembling part of the object.

The disclosure further provides a soldering component, comprising: a body part and an assembling part, the assembling part is for combining to the object, the body part has a snap-fit part, the snap-fit part has a head and a neck for horizontally fastening to the object.

By the above structure, the soldering component of the disclosure can complete the fastening or unfastening of another object, and achieve the purpose of repeated and quick fastening or unfastening.

Optionally, there is a supporting part below the snap-fit part of the body part, and the supporting part is used to make the fastened another object stuck.

Optionally, the assembling part has a shoulder, and the shoulder may be supported by the combined part of the object.

Optionally, the soldering component is combined in a combined part of the object, and the combined part is a passing part, concave part, convex part, groove part, hole part or plane part.

Optionally, the assembling part of the object is placed on a plane, surface, inside a passing part or on the surface of the passing part of the object.

Optionally, the snap-fit part has two or more fastening parts, there is an elastic retracting space among each fastening part, and the elastic retracting space can be elastically retracted, so that each fastening part fastens into another object.

Optionally, the assembling part of the soldering component is placed at the assembling part of the object for soldering to the assembling part of the object after heating.

Optionally, the assembling part of the soldering component is placed at the assembling part of the object, and the assembling part of the object is preset with a tin soldering layer, which is heated and soldered the soldering component and the assembling part of the object.

Optionally, the soldering component is preset in the carrier, the carrier has a cover, and after the cover is opened, the soldering component is picked up by the tool, and placed on the object for soldering.

Optionally, the soldering component is preset in a carrier, and is picked up by a tool, after matched with an assembly position of the object by a matching device, the soldering component is placed at the assembly position by the tool, so that the soldering component is combined to the object.

Optionally, the solderable surface of the soldering component or the solderable surface of the object for combining and soldering is a copper layer, tin layer or nickel layer.

Optionally, the soldering component preset in a carrier is picked up by a tool, and after matched with an assembly position of the object by a matching device, the soldering component is placed at the assembly position by the tool, so that the soldering component is combined to the object, the tool is vacuum suction tool, buckle, fixture, or magnetic suction tool.

Optionally, the soldering component preset in a carrier is picked up by a tool, and after matched by a matching device, the soldering component is placed at the assembly position by the tool, the matching device is a visual matching device, image matching device, distance matching device or computer matching device.

Optionally, the snap-fit part has two or more fastening parts, each fastening part has a guiding surface, when it guides another object to be fastened, the elastic retracting space can be elastically retracted.

Optionally, the snap-fit part is a thread body, protrusion fastening body, column, inner fastening body, I-shaped, fastening body with a head and a neck, inner thread body, inner hole body, fastening body combining movably with the body part, lateral fastening body or handle body, elastically fastening body.

Optionally, the soldering component has an intermediary, the tool picks up the soldering component by the intermediary, and after the soldering component is matched with the assembly position of the object by the matching device, the soldering component is set at an assembly position, and combined to the object.

Optionally, the soldering component has an intermediary, the tool picks up the soldering component by the intermediary to set at the assembly position of the object for conducting a combination, and after the combination is completed, the intermediary is removed.

Optionally, the intermediary is a sheet or a clasp.

Optionally, there is a supporting part between the fastening joint and the assembling part, and the supporting part is used to define a position of the assembling part fastening to the object, and to support a position after another object fastening into the snap-fit part.

Optionally, the object is a printed circuit board.

Optionally, the carrier is a tape-on-reel or a tray.

Optionally, after the soldering component is picked up from the assembling part by the tool, the soldering component is placed at the assembly position of the obj ect.

Optionally, the width of the assembling part is greater than the combined part of the object, the width of the snap-fit part is less than the combined part of the object, the snap-fit part is first passed and set in the combined part, and then the assembling part is assembled to the object.

Optionally, a width of a position limiting part of the body is less than that of the combined part of the object, and the width of the position limiting part is greater than that of the snap part, which is used to pass and set in the combined part, corresponding to the combined part to limit the space and position.

Optionally, the body part has an elastic component, the elastic component vertically or horizontally abuts against the snap-fit part, so that the elastic component can provide a reciprocating elastic force.

Optionally, the snap-fit part is a fastening part integrally formed with the body part, or the snap-fit part is a structure having a cut groove among each fastening part, and integrally formed with the body part, or the snap-fit part is a fastening body fastened to the body part, or the snap-fit part is a ball or rolling body fastened to the body part.

Optionally, the snap-fit part has an outer diameter greater than that of a fastened structure of another object that is correspondingly fastened thereto, which is used to be contracted to pass through the fastened structure by a force interference from top to bottom or from bottom to top, and then the snap-fit part can return to the original size to fasten the fastened structure for fastening to another object.

Optionally, the soldering component further comprises a body part and an assembling part, the assembling part is used to assemble an object, the body part has a snap-fit part, the snap-fit part has an elastic retracting space, and the elastic retracting space can elastically retract two or more fastening parts, so that each fastening part fastens into another object.

Optionally, the snap-fit part has an outer diameter greater than that of a fastened structure of another object that is correspondingly fastened thereto, which is used to be contracted to pass through the fastened structure by a horizontal force interference, and then the snap-fit part can return to the original size to fasten the fastened structure, so that each fastening part fastens into another object.

Optionally, the snap-fit part has an outer diameter greater than that of an opening part of a fastened structure of another object that is correspondingly fastened thereto, which is used to be contracted to pass through the opening part of the fastened structure by a horizontal force interference, and then the snap-fit part can return to the original size, so that each fastening part fastens into a fastening into part of the fastened structure that is greater than the opening part, so as to fasten to another object.

Optionally, the body part has an anti-rotation part, the anti-rotation part is passed and set in the object, the object has a corresponding anti-rotation part, the anti-rotation part and the corresponding anti-rotation part are anti-rotational mutually.

Optionally, there is a tin soldering layer for fixedly connecting between the anti-rotation part and the corresponding anti-rotation part.

Optionally, there is a tin soldering layer for fixedly connecting between the assembling part and the body.

Optionally, the body part has a fixedly connecting part, the fixedly connecting part fastens to a corresponding fixedly connecting part, and is used to fixedly connect with each other after the body part is soldered to the object.

Optionally, the snap-fit part is a handle, which is used to snap-fit a corresponding applying force tool, or used to snap-fit the corresponding applying force human hand or human finger.

Optionally, the assembling part has a stock accommodating space, the assembly position of the object has an opening, and after the stock accommodating space of the soldering component sets in the opening of the object, the assembling part is pressed by an external force, so that the material around the opening flows into or enters the stock accommodating space.

Optionally, the assembling part has an expansion joint, the assembly position of the object has an opening, and after the expansion joint of the soldering component sets in the opening of the object, the expansion joint is pressed by an external force to deform the expansion joint outward for connecting around the opening.

Optionally, the assembling part has a fastening joint, the assembly position of the object has an opening, and after the fastening joint of the assembling part sets in the opening of the object, the fastening joint fastens around the opening.

Optionally, after the fastening joint fastens a fastening body, the fastening joint is set around the opening.

Optionally, the assembling part has a locking joint, the assembly position of the object has an opening, and after the locking joint of the assembling part sets in the opening of the object, the locking joint locks around the opening.

Optionally, after the locking joint locks a locking body, the locking joint is set around the opening.

Optionally, the object is a metal plate, metal block, plastic plate, plastic block, PCB or printed circuit board.

The disclosure further provides a method of assembling a soldering component to an object, wherein the soldering component has a body part and a snap-fit part, the method comprising the following steps: providing a tool to pick up the soldering component; using the tool to move the soldering component to a preset height over an assembly position of the object; and loosening or releasing the soldering component from the tool to make the soldering component set at the assembly position of the object.

The disclosure further provides a method of assembling a soldering component to an object, wherein the soldering component has a body part and a snap-fit part, the method comprising the following steps: providing a tool to pick up the soldering component; using the tool to move the soldering component to an assembly position of the object; and using the tool to press downwards the soldering component, loosening or releasing the soldering component from the tool to make the soldering component set at the assembly position of the object.

The disclosure further provides a method of assembling a soldering component to an object, wherein the soldering component has a body part and a snap-fit part, the method comprising the following steps: providing a tool to pick up the soldering component; using the tool to move the soldering component to an assembly position of the object; and using the tool to elastically press downwards the soldering component, loosening or releasing the soldering component from the tool to make the soldering component set at the assembly position of the object.

The disclosure further provides a method of assembling a soldering component to an object, wherein the soldering component has a body part and a snap-fit part, the method comprising the following steps: providing a tool to pick up the soldering component; using the tool to move the soldering component to an assembly position of the object; and using the tool to sense a feedback message of the soldering component contacting with the object, loosening or releasing the soldering component from the tool to make the soldering component set at the assembly position of the object.

The disclosure further provides a method of assembling a soldering component to an object, wherein the soldering component has a body part and a snap-fit part, the method comprising the following steps: providing a tool to pick up the soldering component; using the tool to move the soldering component to an assembly position of the object; and loosening or releasing the soldering component from the tool to make the soldering component set at the assembly position of the object.

Optionally, the method further comprises the following steps: providing a matching device to match an assembly position or an assembly distance of the soldering component to the object after the soldering component is picked up by the tool; using the tool to move the soldering component to a preset height a over an assembly position of the object according to matching information of the matching device; loosening or releasing the soldering component from the tool to make the soldering component fall to the assembly position of the object.

Optionally, the method further comprises the following steps: providing a matching device to match a position or a distance of the soldering component to an assembling part of the object after the soldering component is picked up by the tool; using the tool to move the soldering component to a preset height over the assembling part of the object according to matching information of the matching device; loosening or releasing the soldering component from the tool to make the soldering component fall to the assembling part of the object.

Optionally, the method further comprises the following steps: providing a matching device to match an assembly position or an assembly distance of the soldering component to the object after the soldering component is picked up by the tool; using the tool to move the soldering component to the assembly position of the object according to matching information of the matching device.

Optionally, a matching device is provided to match a position or a distance of the soldering component to the assembling part of the object after the soldering component is picked up by the tool; the tool is used to move the soldering component to the assembling part of the object according to matching information of the matching device.

Optionally, the tool is a fixture, buckle, vacuum suction device, magnetic suction device or elastic motion component.

Optionally, the body part and the snap-fit part are two independent components combined movably with each other.

Optionally, the matching device is a visual matching device, distance matching device, image matching device, AI matching device or photography matching device.

Optionally, there is a tin soldering layer between the assembling part and the object, the tin soldering layer is for fixedly connecting after cooling.

Optionally, the carrier has a cover to prevent the soldering component from disengaging from the carrier.

Optionally, the snap-fit part that is connected movably with the body part may be an intermediary.

Optionally, the body part and the snap-fit part are two independent components combined movably with each other, wherein an elastic component is further comprised, one end of the elastic component abuts against the body part, and the other end thereof abuts against the snap-fit part, so that the snap-fit part is located at a position where it is put up by the elastic component, or the snap-fit part is located at a position where it is tightly pulled by the elastic component.

Optionally, the snap-fit part may be a thread part, column, hole body, groove body, fastening body, elastic fastening body, inner fastening body, outer fastening body, lateral fastening body or rotational fastening body.

Optionally, the snap-fit part may be a thread part, column, screw nut, stud, sliding fastening body, I-shaped fastening body, hole body, groove body, fastening body, elastic fastening body, inner fastening body, outer fastening body, lateral fastening body or rotational fastening body, wherein the body part and the snap-fit part may be two objects combined movably with each other, or formed in combination, or formed integrally, or that are an identical object.

Optionally, the soldering component has a body part or an assembling part, the method further comprises the following steps: providing a matching device to match an assembly position or an assembly distance of the body part or the assembling part of the soldering component to the object after the soldering component is picked up by the tool; using the tool to move the soldering component to the assembly position of the object according to matching information of the matching device.

Optionally, the body part is just an assembling part.

Optionally, the tool comprises a pickup piece and a moving piece movable relative to the pickup piece, an elastic component is set between the pickup piece and the moving piece, the elastic component is compressed when the moving piece moves relative to the pickup piece.

Optionally, the soldering component has a body part or an assembling part, the method further comprises the following steps: the assembly position of the object is a plane with a tin solder, or a hole part with a tin solder around, or a hole part with a solderable layer inside, wherein the matching device sends the information to the tool for adjusting or correcting the placing position of the body part or the assembling part, in order to move the soldering component to the assembly position of the object.

Optionally, the matching device may be an image matching device, structural matching device, AI matching device or picture matching device; the tool may be a fixture, vacuum device, pneumatic device, magnetic suction device or fastener.

In order to further clearly illustrate the embodiment of the present disclosure or the technical solution in the state of the art, the following will be a brief introduction to the drawings required to be used for describing embodiments, it is obvious that the drawings described below are only some embodiments of the present disclosure, a person having ordinary skill in the art can also obtain other drawings based on these drawings without paying creative labor.

### BRIEF DESCRIPTION OF THE DRAWINGS

FIG. 1 is a schematic side view of state according to the first preferable embodiment of the present disclosure.

FIG. 2 is a schematic side view of state according to the second preferable embodiment of the present disclosure.

FIG. 3 is a schematic side view of state according to the third preferable embodiment of the present disclosure.

FIG. 4 is a schematic side view of state according to the fourth preferable embodiment of the present disclosure.

FIG. 5 is a schematic side view of state according to the fifth preferable embodiment of the present disclosure.

FIG. 6 is a schematic side view of state according to the sixth preferable embodiment of the present disclosure.

FIG. 7 is a schematic side view of state according to the seventh preferable embodiment of the present disclosure.

FIG. 8 is a schematic view 1 of state of use of the present disclosure.

FIG. 9 is a schematic view 2 of state of use of the present disclosure.

FIG. 10 is a schematic view 3 of state of use of the present disclosure.

FIG. 11 is a schematic view of different type of an object of the present disclosure.

FIG. 12 is a schematic view of different type of a snap-fit part of the present disclosure.

FIG. 13 is a schematic view of different type of a carrier of the present disclosure.

FIG. 14 is a schematic view 4 of state of use of the present disclosure.

FIG. 15 is a schematic view 5 of state of use of the present disclosure.

FIG. 16 is a schematic view 6 of state of use of the present disclosure.

FIG. 17 is a schematic view 7 of state of use of the present disclosure.

FIG. 18 is a schematic view 8 of state of use of the present disclosure.

FIG. 19 is a schematic side view of state according to the eighth preferable embodiment of the present disclosure.

FIG. 20 is a schematic side view of state according to the ninth preferable embodiment of the present disclosure.

FIG. 21 is a schematic view 1 of state of use according to the tenth preferable embodiment of the present disclosure.

FIG. 22 is a schematic view 2 of state of use according to the tenth preferable embodiment of the present disclosure.

FIG. 23 is a schematic view of a soldering component assembling to an object of the present disclosure.

FIG. 24 is a schematic view 1 of a soldering component assembling to an object of the present disclosure.

FIG. 25 is a schematic view 2 of a soldering component assembling to an object of the present disclosure.

FIG. 26 is a schematic view of state of use according to the eleventh preferable embodiment of the present disclosure.

FIG. 27 is a schematic view of state of use according to the twelfth preferable embodiment of the present disclosure.

FIG. 28 is a schematic view of state of use according to the thirteenth preferable embodiment of the present disclosure.

FIG. 29 is a schematic view of state of use according to the fourteenth preferable embodiment of the present disclosure.

FIG. 30 is a schematic view of state of use according to the fifteenth preferable embodiment of the present disclosure.

FIG. 31 is a schematic view of state of use according to the sixteenth preferable embodiment of the present disclosure.

FIG. 32 is a schematic view 1 of different type of the snap-fit part of the present disclosure.

FIG. 33 is a schematic view 2 of different type of the snap-fit part of the present disclosure.

FIG. 34 is a schematic view 3 of different type of the snap-fit part of the present disclosure.

FIG. 35 is a schematic view 1 of state of use according to the seventeenth preferable embodiment of the present disclosure.

FIG. 36 is a schematic view 2 of state of use according to the seventeenth preferable embodiment of the present disclosure.

FIG. 37 is a schematic view 1 of state of use according to the eighteenth preferable embodiment of the present disclosure.

FIG. 38 is a schematic view 2 of state of use according to the eighteenth preferable embodiment of the present disclosure.

FIG. 39 is a schematic view of state of use according to the nineteenth preferable embodiment of the present disclosure.

FIG. 40 is a schematic view of state of use according to the twentieth preferable embodiment of the present disclosure.

FIG. 41A is a schematic view 1 of state of use according to the twenty-first preferable embodiment of the present disclosure.

FIG. 41B is a schematic view 2 of state of use according to the twenty-first preferable embodiment of the present disclosure.

FIG. 42A is a schematic view 1 of state of use according to the twenty-second preferable embodiment of the present disclosure.

FIG. 42B is a schematic view 2 of state of use according to the twenty-second preferable embodiment of the present disclosure.

FIG. 43 is a schematic view of the twenty-third embodiment of the present disclosure.

FIG. 44 is a schematic view of the twenty-fourth embodiment of the present disclosure.

FIG. 45 is a schematic view of the twenty-fifth embodiment of the present disclosure.

FIG. 46 is a schematic view of the twenty-sixth embodiment of the present disclosure.

FIG. 47 is a schematic view of the twenty-seventh embodiment of the present disclosure.

FIG. 48 is a schematic view of the twenty-eighth embodiment of the present disclosure.

FIG. 49 is a schematic view of the twenty-ninth embodiment of the present disclosure.

### DETAILED DESCRIPTION OF THE INVETION

The following will be combined with the drawings to further illustrate a soldering component and a method of assembling the soldering component on an object of the embodiments of the present disclosure.

The aforementioned and other technical contents, characteristics and effects of the present disclosure can be clearly presented by the detailed description of preferable embodiments together with the attached drawings. It’s worth mentioning that the direction terms mentioned in the following embodiments, such as: top, bottom, left, right, front or back, etc., are only referred to the direction of the drawings. Therefore, the directional terms used are intended to illustrate, not to limit, the disclosure. In addition, in the following embodiments, the same or similar components will use the same or similar reference numerals.

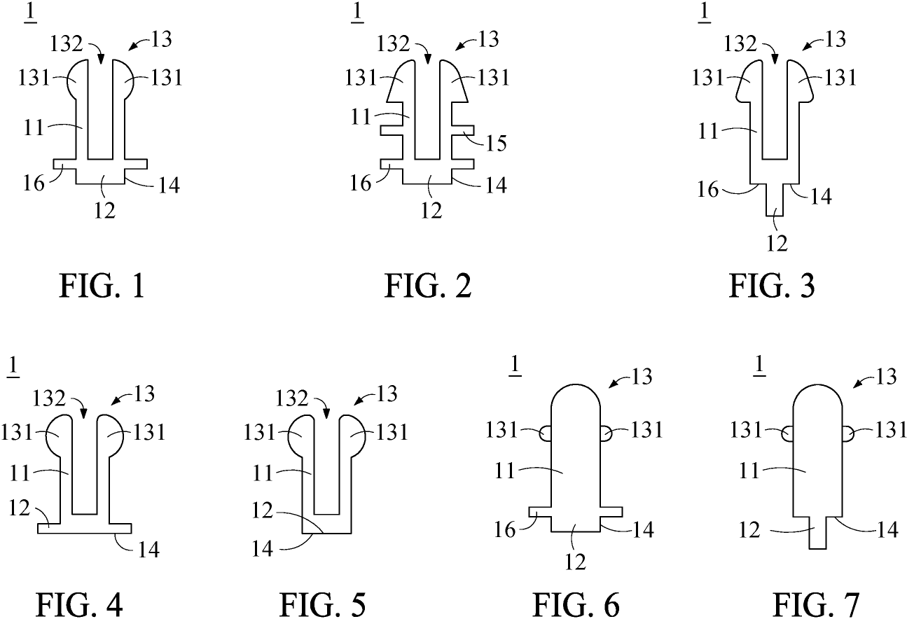

Referring to FIGS. 1 to 13, as shown in the drawings, the disclosure provides a soldering component and a method of assembling the soldering component on an object, and the soldering component 1 (shown as FIGS. 1 to 7) comprises a body part 11 and an assembling part 12, the body part 11 has a snap-fit part 13, and the soldering component 1 has a solderable surface 14 for soldering and combining to an object 2 (the object 2 may be a metal plate, metal block, plastic plate, plastic block, PCB or printed circuit board).

In the disclosure, the snap-fit part 13 has an elastic retracting space 132 (as shown in FIGS. 1 to 5), and the elastic retracting space 132 can elastically retract two or more fastening parts 131, so that each fastening part 131 fastens into another object 6 (as shown in FIG. 9).

In addition, the snap-fit part 13 has an outer diameter greater than that of a fastened structure of another object 6 that is correspondingly fastened thereto, which is used to be contracted to pass through the fastened structure by a force interference from top to bottom or from bottom to top, and then the snap-fit part 13 can return to the original size to fasten the fastened structure, so that each fastening part 131 fastens into another object 6.

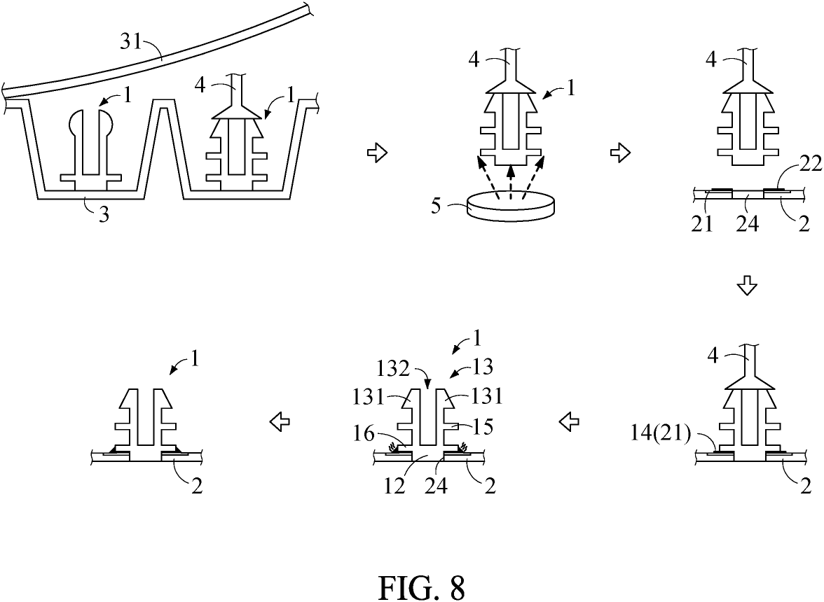

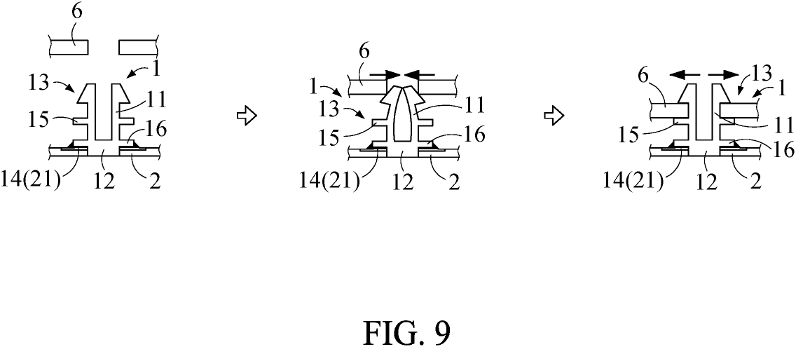

In the disclosure, the soldering component 1 is used to be stored in a carrier 3 (or preset in a carrier 3), and is picked up by a tool 4, after matched with an assembly position of the object 2 by a matching device 5, the soldering component is placed at the assembly position by the tool 4, so that the soldering component 1 is combined to the object 2 (as shown in FIG. 8).

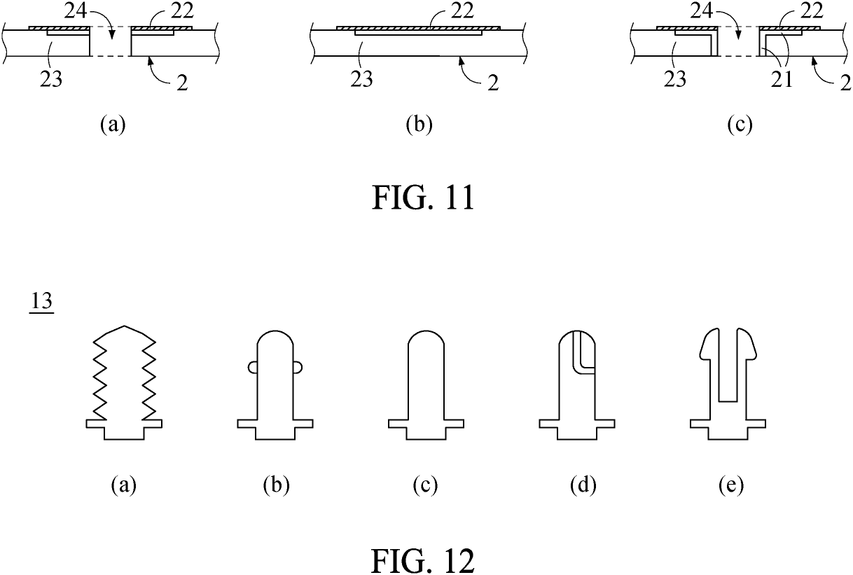

In the disclosure, the soldering component 1 has a solderable surface 14 for soldering to an assembling part 21 of the object, the assembling part 21 of the object is preset with a tin soldering layer 22, which is heated and soldered the solderable surface 14 of the soldering component 1 and the solderable surface 21 of the object 2, so that the soldering component 1 is combined with the object 2. A non-solderable layer 23 of the object 2 is below the assembling part 21 of the object, wherein the assembling part 21 of the object is placed on a plane, surface, inside a passing part or on the surface of the passing part of the object 2; in addition, the soldering component 1 is combined to a combined part 24 of the object 2, and the combined part 24 is the passing part (as shown in part a, c of FIG. 11), a concave part, convex part, groove part, hole part or plane part (as shown in part b of FIG. 11).

When used (as shown in FIGS. 8, 9 and 10), the soldering component 1 may be first preset in the carrier 3, and the soldering component 1 is picked by the tool 4, and after matched with the assembly position of the object 2 by the matching device 5, the soldering component is placed at the assembly position by the tool 4 to make the solderable surface 14 of the soldering component 1 soldered to the assembling part 21 of the object after heating, so that the soldering component 1 is combined to the object 2, and then another object 6 may be fastened to the snap-fit part 13 through each fastening part 131 going with the elastic retracting space 132, or unfastened by the snap-fit part 13. Accordingly, the soldering component 1 can be fastened or unfastened so as to complete the fastening or unfastening of another object, and achieve the purpose of repeated and quick fastening or unfastening.

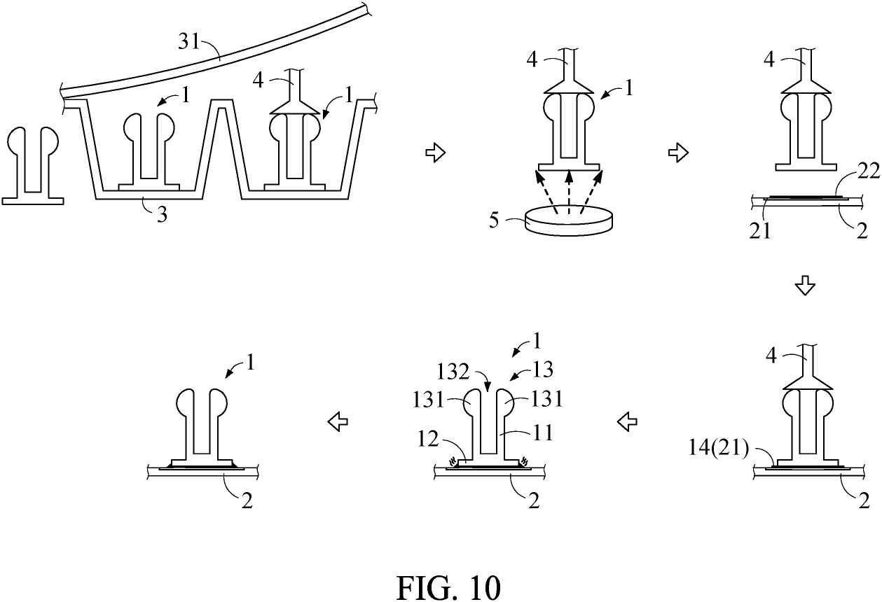

In an embodiment of the disclosure, there is a tin soldering layer 22 for fixedly connecting between the assembling part 12 and the object 2 (as shown in FIG. 10).

In an embodiment of the disclosure, there is a supporting part 15 below the snap-fit part 13 of the body part 11 (as shown in FIGS. 2, 8 and 9), and the supporting part 15 is used to make the fastened another object 6 stuck. Also, the supporting part 15 is used to define a position of the assembling part 12 fastening to the object 2, and to support a position after another object 6 fastening into the snap-fit part 13. Accordingly, the soldering component 1 can be firmly combined with another object 6.

In an embodiment of the disclosure, the body part 11 has a fixedly connecting part 113, the fixedly connecting part 113 fastens to a corresponding fixedly connecting part 26, and is used to fixedly connect with each other after the body part 11 is soldered to the object 2, so as to firmly assemble the soldering component 1 with the object 2.

In an embodiment of the disclosure, the assembling part 12 has a shoulder 16 (as shown in FIG. 1, FIG. 2, FIG. 3, FIG. 6 and FIG. 7), and the shoulder 16 may be supported by the combined part 24 of the object 2. Accordingly, the soldering component 1 can be firmly combined with the object 2.

In an embodiment of the disclosure, the solderable surface 14 of the soldering component 1 is set at the assembling part 12, which is heated and soldered to the assembling part 21 of the object. Accordingly, the soldering component 1 can be firmly combined with the object 2.

In an embodiment of the disclosure, the snap-fit part 13 may be a thread body (as shown in part a of FIG. 12), protrusion fastening body (as shown in part b of FIG. 12), column (as shown in part c of FIG. 12), inner fastening body (as shown in part d of FIG. 12) or elastically fastening body (shown in part e of FIG. 12); in addition, the snap-fit part 13 may also be set as I-shaped, fastening body with a head and a neck, inner thread body, inner hole body, fastening body combining movably with the body part, lateral fastening body or handle body. Accordingly, the present disclosure can further meet the requirement of practical application.

In addition, the snap-fit part 13 is a fastening part integrally formed with the body part 11, or the snap-fit part 13 is a structure having a cut groove among each fastening part, and integrally formed with the body part 11, or the snap-fit part 13 is a fastening body fastened to the body part 11, or the snap-fit part 13 is a ball or rolling body fastened to the body part 11.

In an embodiment of the disclosure, the solderable surface 14 of the soldering component 1 or the solderable surface 21 of the object 2 for combining and soldering is a copper layer, tin layer or nickel layer. Accordingly, the present disclosure can further meet the requirement of practical application.

In an embodiment of the disclosure, the carrier 3 has a cover 31 to prevent the soldering component 1 from disengaging from the carrier 3 (as shown in FIG. 8 and FIG. 10), and after the cover 31 is opened, the soldering component 1 is picked up by the tool, and set on the object 2 for soldering. Accordingly, the present disclosure can further meet the requirement of practical application.

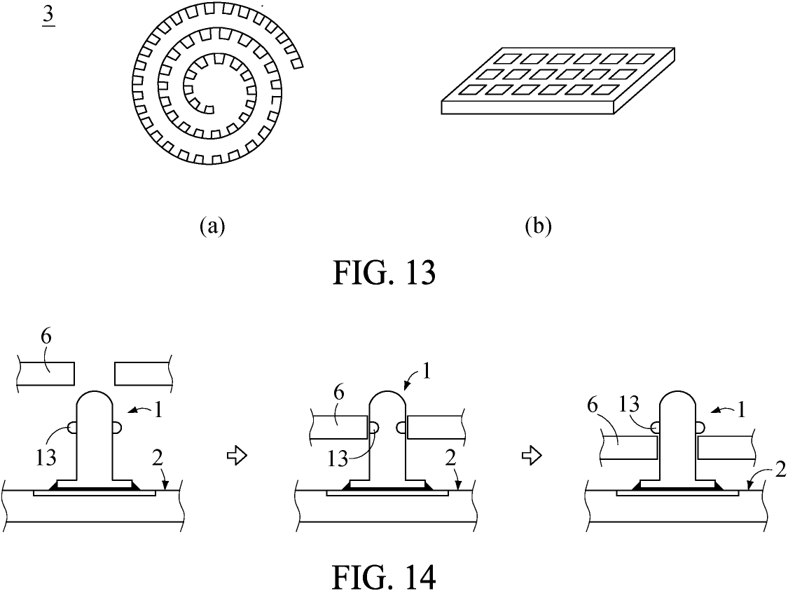

In an embodiment of the disclosure, the soldering component 1 is set in the carrier 3, the carrier 3 is a tape-on-reel (as shown in part a of FIG. 13) or a tray (as shown in part b of FIG. 13). Accordingly, the present disclosure can further meet the requirement of practical application.

In an embodiment of the disclosure, the tool 4 is a vacuum suction tool, buckle, fixture, or magnetic suction tool, vacuum device, pneumatic device, magnetic suction device or fastener. Accordingly, the present disclosure can further meet the requirement of practical application.

In an embodiment of the disclosure, the matching device 5 is a visual matching device, image matching device, distance matching device, computer matching device, structural matching device, AI matching device or picture matching device. Accordingly, the present disclosure can further meet the requirement of practical application.

Further, as shown in FIG. 14, the snap-fit part 13 is a protrusion fastening body in the embodiment. After the soldering component 1 is combined to the object 2, another object 6 is fastened through the snap-fit part 13, or unfastened by the snap-fit part 13. Accordingly, the soldering component 1 can be fastened or unfastened so as to complete the fastening or unfastening of another object, and achieve the purpose of repeated and quick fastening or unfastening.

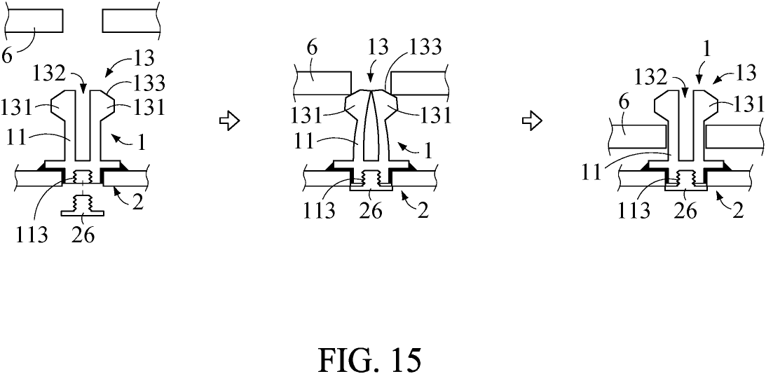

Further, as shown in FIG. 15, the embodiment is different from the above each embodiment in that each fastening part 131 has a guiding surface 133 for guiding another object 6 to fasten into the snap-fit part 13, so that the elastic retracting space 132 can be elastically retracted, allowing another object 6 to be fastened through the fastening part 13, or unfastened by the snap-fit part 13. Accordingly, the soldering component 1 can be fastened or unfastened so as to complete the fastening or unfastening of another object, and achieve the purpose of repeated and quick fastening or unfastening.

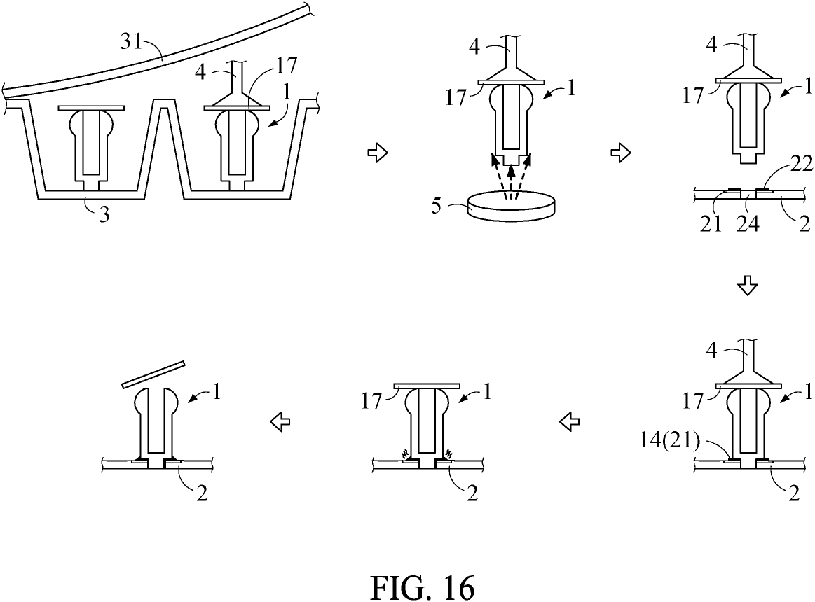

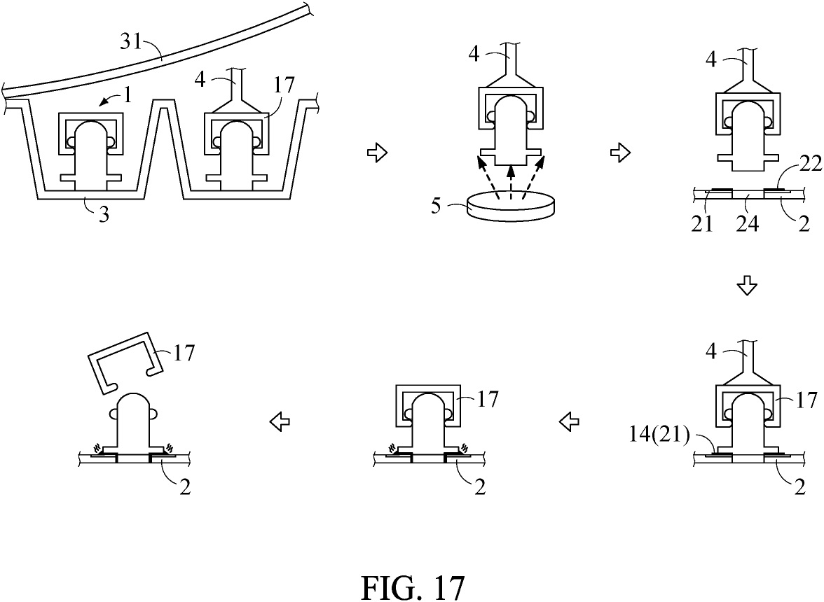

Further, as shown in FIGS. 16 and 17, the embodiment is different from the above each embodiment in that the soldering component 1 has an intermediary 17, the tool 4 may pick up the soldering component 1 by the intermediary 17, and after the soldering component 1 is matched with the assembly position of the object 2 by the matching device 5, the soldering component 1 is set at a soldering position, and soldered to the object 2 for conducting a combination. Accordingly, the present disclosure can further meet the requirement of practical application.

In an embodiment of the disclosure, after the tool 4 picks up the soldering component 1 to set at the assembly position of the object 2 for soldering by the intermediary 17, the intermediary 17 may be removed in order to fasten another object 6 through the snap-fit part 13. Accordingly, the present disclosure can further meet the requirement of practical application.

In an embodiment of the disclosure, the intermediary 17 is a sheet (as shown in FIG. 16) or a clasp (as shown in FIG. 17). Accordingly, the present disclosure can further meet the requirement of practical application.

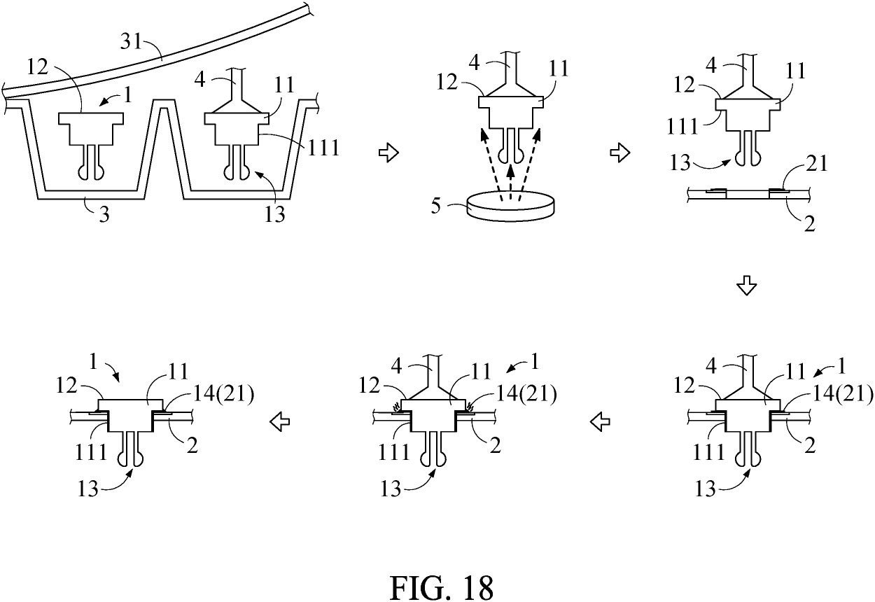

Further, as shown in FIG. 18, the embodiment is different from the above each embodiment in that the tool 4 may pick up the soldering component 1 from the position of the assembling part 12, and then set the soldering component 1 at the assembly position of the object 2 to heat and solder the solderable surface 14 of the soldering component 1 and the assembling part 21 of the object, so that the soldering component 1 combines to the object 2. Accordingly, the present disclosure can further meet the requirement of practical application.

In an embodiment of the disclosure, the width of the assembling part 12 is greater than the combined part 24 of the object 2, the width of the snap-fit part 13 is less than the combined part 24 of the object, the snap-fit part 13 is first passed and set in the combined part 24, and then the assembling part 12 is assembled to the object 2. Accordingly, the present disclosure can further meet the requirement of practical application.

In an embodiment of the disclosure, a width of a position limiting part 111 of the body 11 is less than that of the combined part 24 of the object 2, and the width of the position limiting part 111 is greater than that of the snap part 13, which is used to pass and set in the combined part 24, corresponding to the combined part 24 to limit the space and position. Accordingly, the present disclosure can further meet the requirement of practical application.

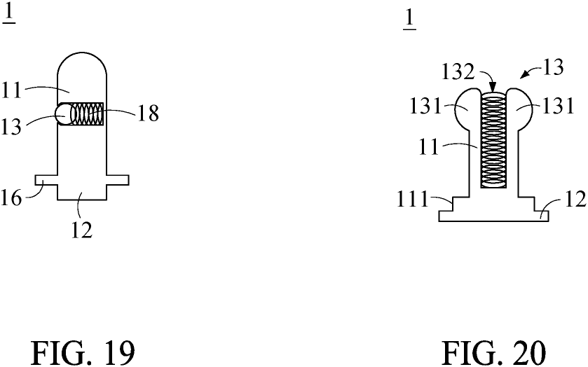

Further, as shown in FIGS. 19 and 20, the embodiment is different from the above each embodiment in that the body part 11 has an elastic component 18, the elastic component 18 vertically or horizontally abuts against the snap-fit part 13, so that the elastic component 18 can provide a reciprocating elastic force when another object (not shown in the figures) conducts fastening through the snap-fit part 13, or unfastening by the snap-fit part 13. Accordingly, the present disclosure can further meet the requirement of practical application.

In an embodiment of the disclosure, the elastic component 18 may be horizontally set between the body part 11 and the snap-fit part 13 (as shown in FIG. 19), or the elastic component 18 may be vertically set between the snap-fit part 13 and each fastening part 131 (for example: set in the elastic retracting space 132, as shown in FIG. 20). Accordingly, the present disclosure can further meet the requirement of practical application.

In addition, the snap-fit part 13 has an outer diameter greater than that of a fastened structure of another object that is correspondingly fastened thereto, which is used to be contracted to pass through the fastened structure by a horizontal force interference, and then the snap-fit part 13 can return to the original size to fasten the fastened structure, so that each fastening part 131 fastens into another object 6 (as shown in FIG. 19).

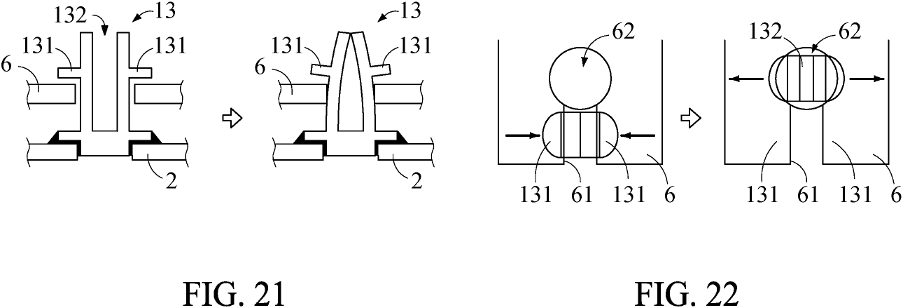

Further, as shown in FIGS. 21 and 22, the embodiment is different from the above each embodiment in that the snap-fit part 13 has an outer diameter greater than that of an opening part 61 of a fastened structure of another object 6 that is correspondingly fastened thereto, which is used to be contracted to pass through the opening part 61 of the fastened structure by a horizontal force interference, and then the snap-fit part 13 can return to the original size, so that each fastening part 131 fastens into a fastening into part 62 of the fastened structure that is greater than the opening part 61, so as to fasten the snap-fit part 13 to another object 6.

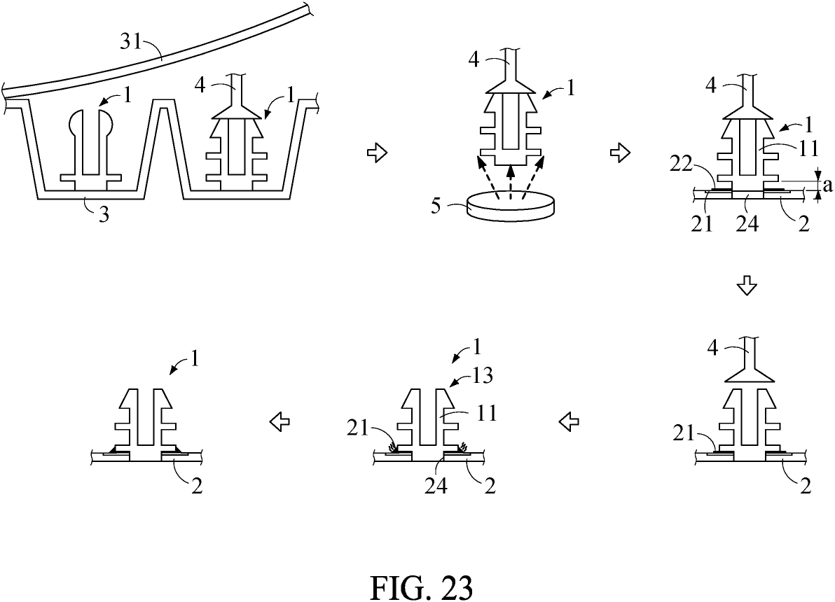

Further, as shown in FIG. 23, the present disclosure provides another method of assembling the soldering component on objects, the soldering component 1 has a body part 11 and a snap-fit part 13, the method comprising the following steps: providing a tool 4 to pick up the soldering component 1; using the tool 4 to move the soldering component 1 to a preset height a over an assembly position of the object 2; and placing part of an assembling part 12 of the soldering component 1 in a combined part 24 (e.g., a combined hole) of the object 2, and loosening or releasing the soldering component 1 from the tool to make the soldering component 1 fall to the assembly position (i.e., the combined part 24) of the object 2, so as to complete the assembly of the soldering component 1 and the object 2.

In an embodiment of the disclosure, the method further comprises the following steps: providing a matching device 5 to match an assembly position or an assembly distance of the soldering component 1 to the object 2 after the soldering component 1 is picked up by the tool 4; using the tool 4 to move the soldering component 1 to a preset height a over an assembly position of the combined part 24 of the object 2 according to matching information of the matching device 5; loosening or releasing the soldering component 1 from the tool 4 to make the soldering component 1 fall to the assembly position of the object 2.

In an embodiment of the disclosure, the method further comprises the following steps: providing a matching device 5 to match a position or a distance of the soldering component 1 to an assembling part 21 of the assembly position of the object 2 after the soldering component 1 is picked up by the tool 4; using the tool 4 to move the soldering component 1 to a preset height over the assembling part 21 of the object according to matching information of the matching device 5; loosening or releasing the soldering component 1 from the tool 4 to make the soldering component 1 fall to the assembling part 21 of the object.

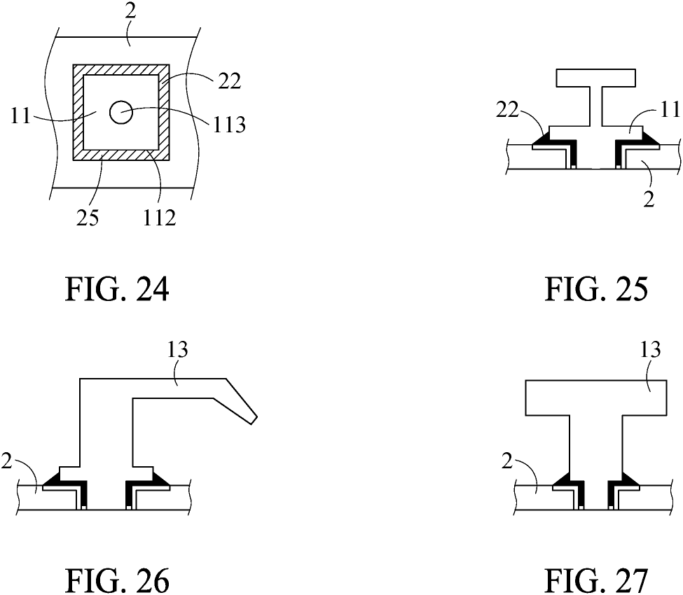

Further, as shown in FIGS. 24 and 25, the body part 11 has an anti-rotation part 112 in the disclosure, the anti-rotation part 112 is passed and set in the object 2, the object 2 has a corresponding anti-rotation part 25, the anti-rotation part 112 and the corresponding anti-rotation part 25 are anti-rotational mutually, so as to complete the assembly of the soldering component 1 and the object 2.

In an embodiment of the disclosure, there is a tin soldering layer 22 for fixedly connecting between the anti-rotation part 112 and the corresponding anti-rotation part 25, so as to firmly assemble the soldering component 1 to the object 2.

Further, as shown in FIGS. 26 and 27, the snap-fit part 13 is a handle, which is used to snap-fit a corresponding applying force tool (e.g., used to snap-fit the corresponding applying force human hand or human finger, robotic arm or other related tools, and so on), so that the present disclosure can further meet the requirement of practical application.

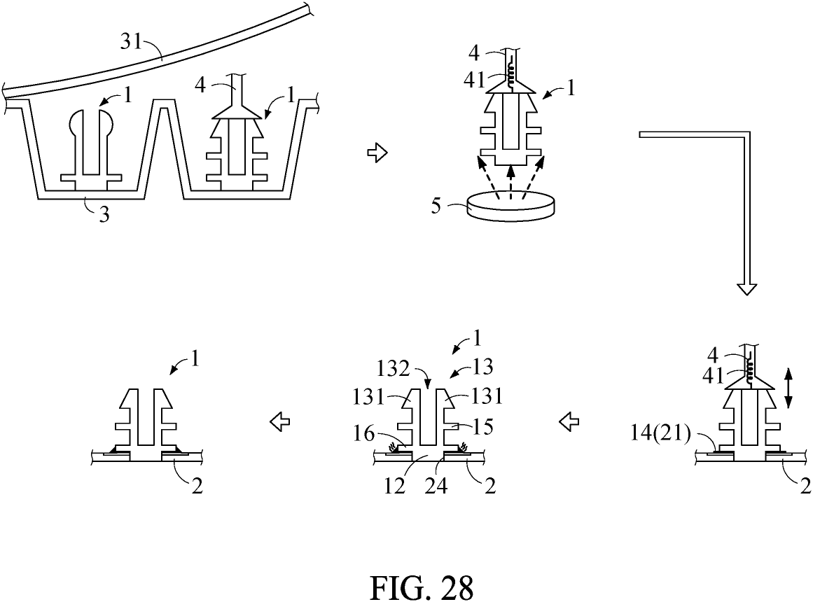

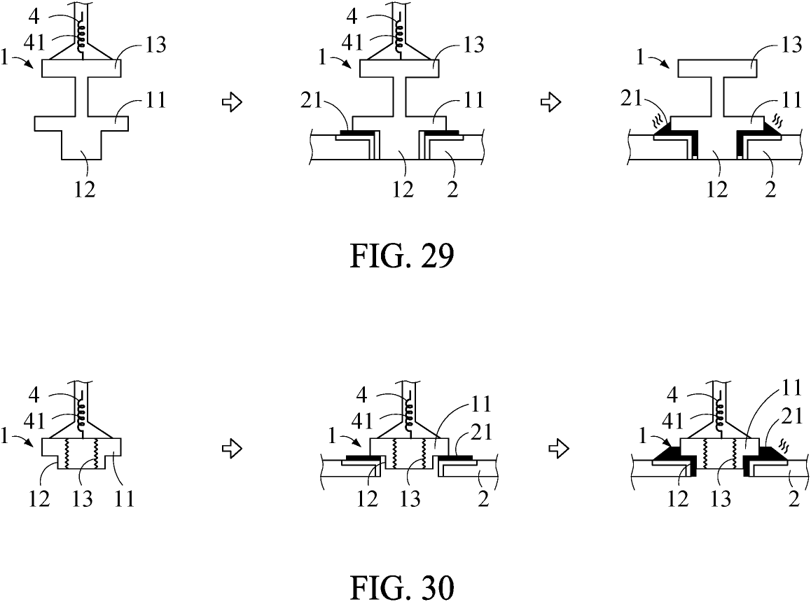

Further, as shown in FIGS. 28 to 30, the present disclosure provides another method of assembling the soldering component on objects, the soldering component 1 has a body part 11 and a snap-fit part 13, the method comprising the following steps: providing a tool 4 to pick up the soldering component 1; using the tool 4 to move the soldering component 1 to an assembly position of the object 2; and using the tool to press downwards the soldering component 1 to make the soldering component 1 pressed downwards to the assembly position of the object 2.

In an embodiment of the disclosure, a matching device 5 is provided to match an assembly position or an assembly distance of the soldering component 1 to the object 2 after the soldering component 1 is picked up by the tool 4; the tool 4 is used to move the soldering component 1 to the assembly position of the object and press downwards the soldering component 1 to make the soldering component 1 pressed downwards to the assembly position of the object 2 according to matching information of the matching device 5.

In an embodiment of the disclosure, the assembly position of the object 2 may be a plane with a tin solder, or a hole part with a tin solder around, or a hole part with a tin soldering layer inside, wherein the matching device 5 sends the information to the tool 4 for adjusting or correcting the placing position of the body part 11 or the assembling part 12, in order to move the soldering component 1 to the assembly position of the object 2.

In an embodiment of the disclosure, a matching device 5 is provided to match a position or a distance of the soldering component 1 to an assembling part 21 of the assembly position of the object 2 after the soldering component 1 is picked up by the tool 4; the tool 4 is used to move the soldering component 1 to the assembling part 21 of the object and the tool 4 is used to press downwards the soldering component 1 to make the soldering component 1 pressed downwards to the assembling part 21 of the object according to matching information of the matching device 5.

In an embodiment of the disclosure, the matching device 5 is a visual matching device, distance matching device, image matching device, AI matching device or photography matching device.

In an embodiment of the disclosure, the method of using the tool 4 to press downwards the soldering component 1 may be elastically pressing.

In an embodiment of the disclosure, the tool 4 is a fixture, buckle, vacuum suction device, magnetic suction device or elastic motion component.

In an embodiment of the disclosure, the tool 4 has an elastic sensor 41, and when the tool 4 moves the soldering component 1 to the assembly position of the object 2, the tool 4 can loosen or release the soldering component 1 after the elastic sensor 41 of the tool 4 senses a feedback message of the soldering component 1 contacting with the object 2, so that the soldering component 1 can be set at the assembly position of the object 2. Accordingly, the present disclosure can further meet the requirement of practical assembly.

In the embodiment of the disclosure, when the soldering component 1 contacts with the object 2, the soldering component 1 contacts with the object 2 to form a state of electrical continuity, so that the elastic sensor 41 senses the electrical continuity and generates a feedback message, and the tool 4 can be driven to loosen or release the soldering component 1 by the feedback message.

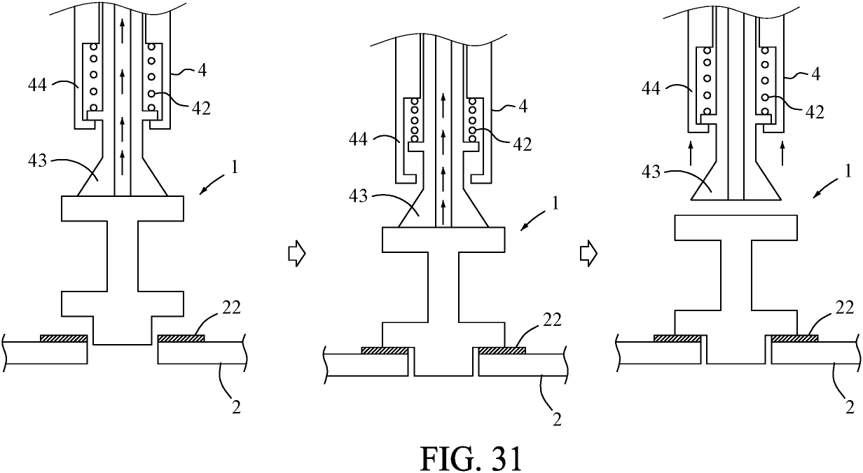

Further, as shown in FIG. 31, in an embodiment of the disclosure, an elastic component 42 within the tool 4 can go with a vacuum suction force of the tool 4 to make the tool 4 pick up the soldering component 1, so that the tool 4 can move the soldering component 1 to the assembly position of the body 2, and the tool 4 elastically presses downwards the soldering component 1 to the body 2, and the elastic component 42 is compressed, and then the vacuum suction force is released to make the elastic component 42 return to the original position, the tool 4 loosens or releases the soldering component 1, so that the soldering component 1 can be placed at the assembly position of the body 2 to meet the requirement of practical assembly.

In an embodiment of the disclosure, the tool 4 comprises a pickup piece 43 and a moving piece 44 movable relative to the pickup piece 43, the elastic component 42 is set between the pickup piece 43 and the moving piece 44, the elastic component 42 is compressed when the moving piece 44 moves relative to the pickup piece 43. The tool 4 is used to move the soldering component 1 to the assembly position of the object 2, and the tool 4 is used to move downwards the moving piece 44 relative to the pickup piece 43 toward the object 2, so that the pickup piece 43 receives a compressed elastic force of the elastic component 42 to elastically press the soldering component 1 to the body 2.

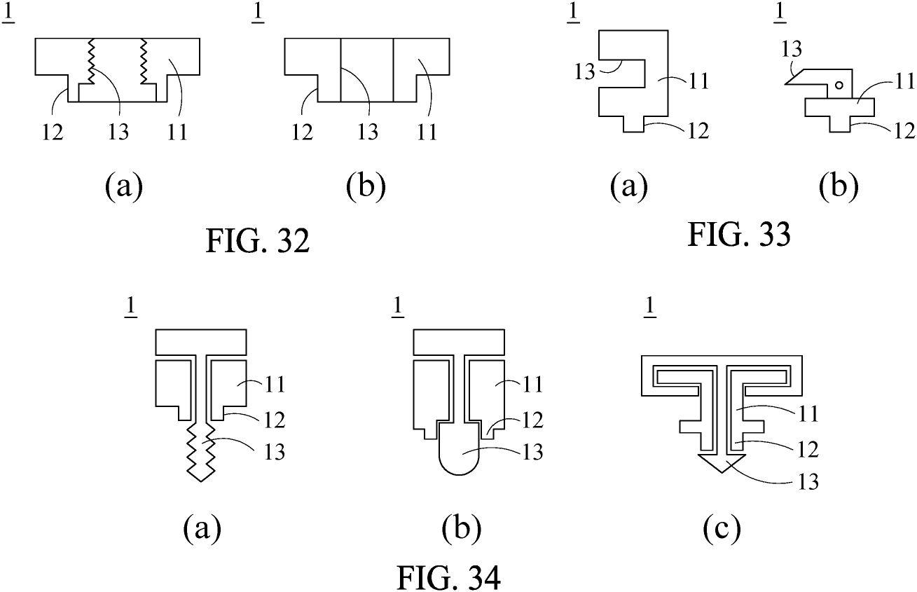

Further, as shown in FIGS. 32 to 34, in an embodiment of the disclosure, the snap-fit part 13 of the soldering component 1 may be an inner thread body (as shown in part a of FIG. 32), inner hole body (as shown in part b of FIG. 32), lateral fastening body (as shown in part a, b of FIG. 33) or fastening body combining movably with the body part 11 (as shown in part a, b of FIG. 34). In addition, the body part 11 and the snap-fit part 13 are two independent components combined movably with each other (as shown in part a, b of FIG. 34), and the snap-fit part 13 that is connected movably with the body part 11 may be an intermediary.

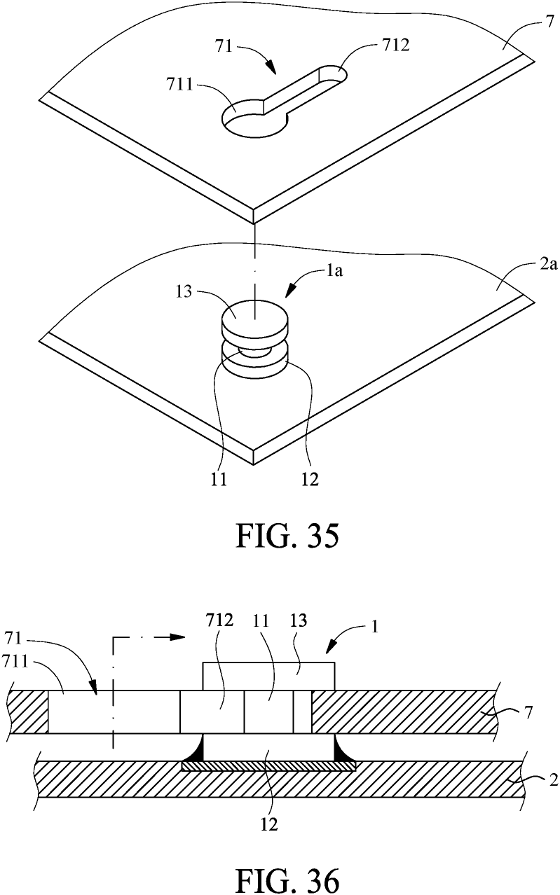

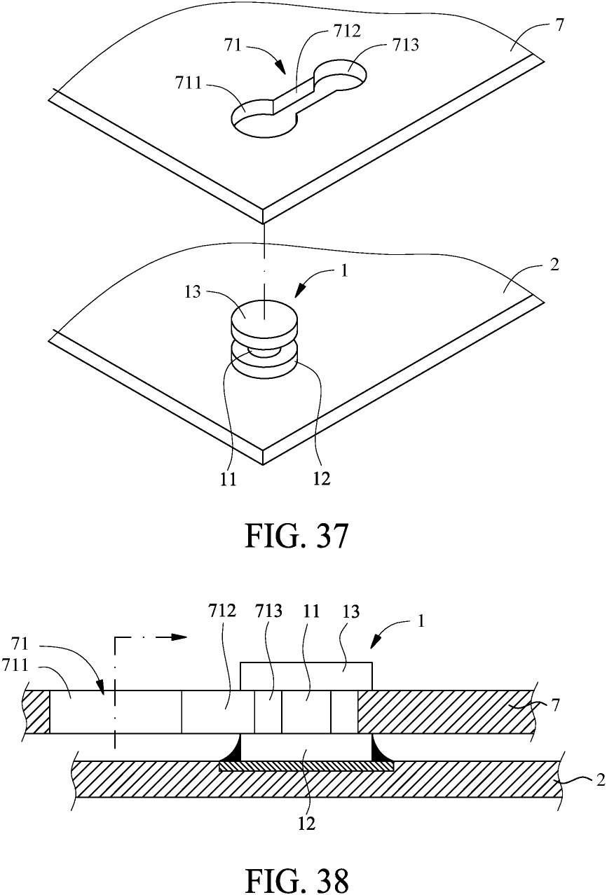

Further, as shown in FIGS. 35 to 38, in an embodiment of the disclosure, the soldering component 1 is used for soldering on the object 2 (as shown in FIGS. 35 and 38), and thus can fasten an assembling object 7 (as shown in FIGS. 37 and 38); After the soldering component 1 and the object 2 form a module member, it is available to use the soldering component 1 to fasten the assembling object 7, as shown in FIGS. 35 and 36, the assembling object 7 may be implemented to have a buckling part 71 going with the snap-fit part 13 and the neck of the soldering component 1, so that the body part 11 of the soldering component 1 is passed and set in the buckling part 71, and the snap-fit part 13 is fastened on the buckling part 71. As shown in FIGS. 35 and 36, the snap-fit part 13 may be implemented to have a perforation 711 with a diameter greater than the snap-fit part 13, and a fastening groove 712 communicated with the perforation 711 and the width thereof being less than the snap-fit part 13. Thus, after the snap-fit part 13 of the soldering component 1 passes through the perforation 711, the assembling object 7 is moved, so that the body part 11 is passed and set in the fastening groove 712, in order to form the structure for fastening the assembling object 7. Alternatively, as shown in FIGS. 37 and 38, the snap-fit part 13 may also be implemented to have a perforation 711 with a diameter greater than the snap-fit part 13, a fastening hole 713 with a diameter less than the snap-fit part 13, and a fastening groove 712 communicated with the perforation 711 and the fastening hole 713, and the width thereof being less than the snap-fit part 13. Thus, after the snap-fit part 13 of the soldering component 1 passes through the perforation 711, the assembling object 7 is moved, so that the body part 11 is passed and set in the fastening groove 712 or the fastening hole 713, in order to form the structure for fastening the assembling object 7. In the reverse operation, the assembling object 7 can be reversely disengaged from the soldering component 1.

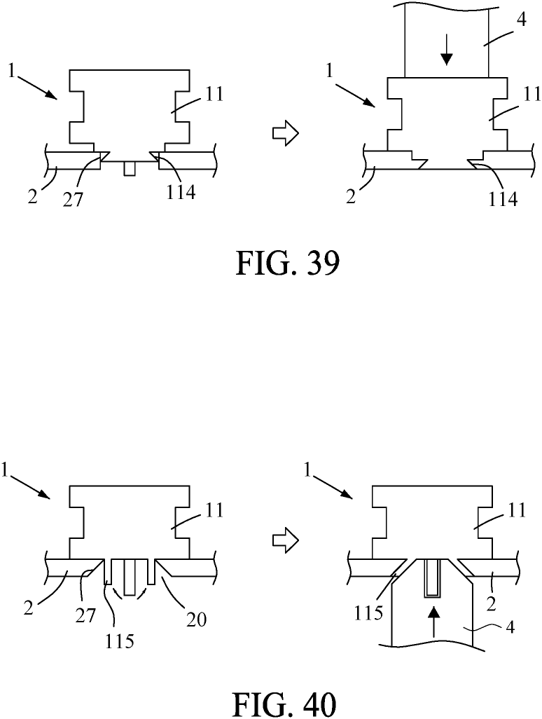

Referring to FIG. 39, as shown in the drawing, in an embodiment of the disclosure, the bottom of the body part 11 of the soldering component 1 may have a stock accommodating space 114, and after the stock accommodating space 114 of the soldering component 1 falls to an opening 27 of the object 2, the soldering component 1 may be pressed by an external force with the tool 4, the body part 11 will apply pressure around the opening 27 so that the material of the object 2 flows into or enters the stock accommodating space 114 to make the soldering component 1 assembled in the obj ect 2.

Referring to FIG. 40, as shown in the drawing, in an embodiment of the disclosure, the bottom of the body part 11 of the soldering component 1 may have an expansion joint 115, and after the expansion joint 115 of the soldering component 1 falls to the opening 27 of the object 2, the expansion joint 115 can be pressed by an external force with the tool 4 to deform the expansion joint 115 outward for connecting around the opening 27 so that the soldering component 1 is assembled in the obj ect 2.

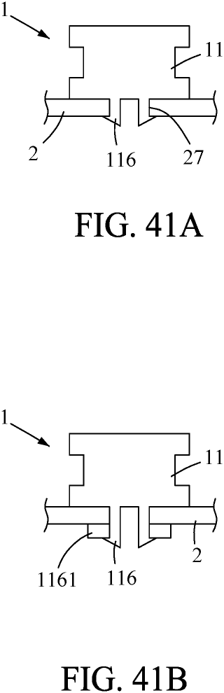

Referring to FIG. 41A, as shown in the drawing, in an embodiment of the disclosure, the bottom of the body part 11 of the soldering component 1 may have a fastening joint 116, and after the fastening joint 116 of the soldering component 1 falls to the opening 27 of the object 2, the fastening joint 116 can fasten around the opening 27 so that the soldering component 1 is assembled in the object 2.

Referring to FIG. 41B, as shown in the drawing, after the fastening joint 116 of the soldering component 1 falls to the opening 27 of the object 2, the fastening joint 116 can fasten a fastening body 1161, and then provided around the opening 27 in an embodiment of the disclosure.

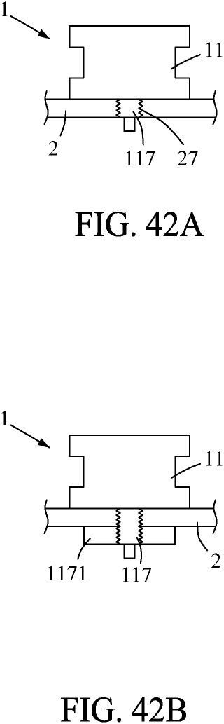

Referring to FIG. 42A, as shown in the drawing, in an embodiment of the disclosure, the bottom of the body part 11 of the soldering component 1 may have a locking joint 117, and after the locking joint 117 of the soldering component 1 falls to the opening 27 of the object 2, the locking joint 117 can lock around the opening 27 so that the soldering component 1 is assembled in the object 2.

Referring to FIG. 42B, as shown in the drawing, after the locking joint 117 of the soldering component 1 falls to the opening 27 of the object 2, the locking joint 117 can lock a locking body 1171, and then provided around the opening 27 in an embodiment of the disclosure.

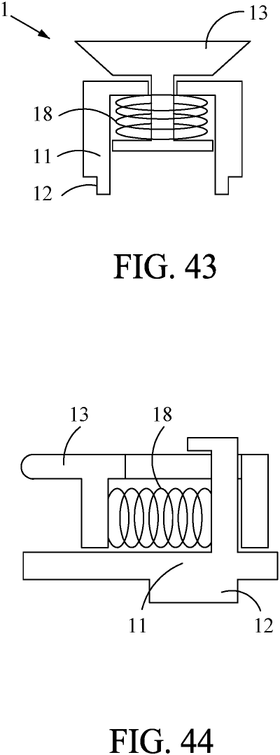

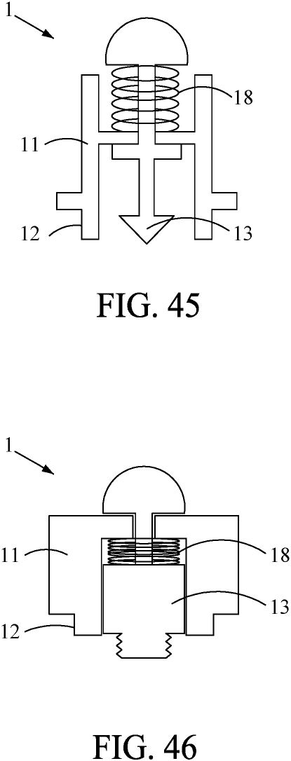

Referring to FIGS. 43 to 46, as shown in the drawings, in an embodiment of the disclosure, the body part 11 and the snap-fit part 13 are two independent components combined movably with each other, wherein an elastic component 18 is further comprised, one end of the elastic component 18 abuts against the body part 11, and the other end thereof abuts against the snap-fit part 13, so that the snap-fit part 13 is located at a position where it is put up by the elastic component 18, or the snap-fit part 13 is located at a position where it is tightly pulled by the elastic component 18.

In the embodiment of the disclosure, the snap-fit part 13 may be a thread part, column, screw nut, stud, sliding fastening body, I-shaped fastening body, hole body, groove body, fastening body, elastic fastening body, inner fastening body, outer fastening body, lateral fastening body or rotational fastening body, wherein the body part 11 and the snap-fit part 13 may be two objects combined movably with each other, or formed in combination, or formed integrally, or that are an identical obj ect.

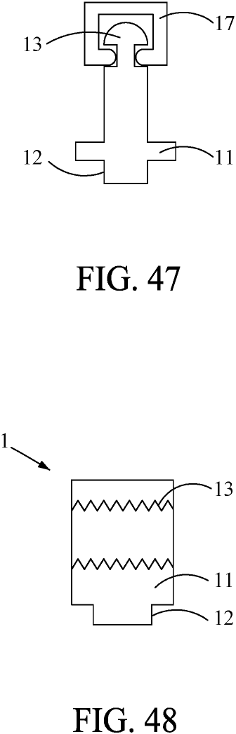

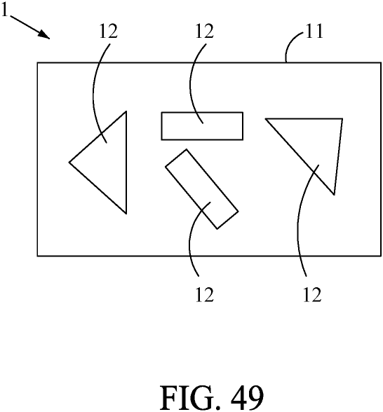

Referring to FIGS. 47 to 49, as shown in the drawings, in an embodiment of the disclosure, the body part 11 is just an assembling part; and as shown in FIG. 47, the intermediary 17 may be combined to the snap-fit part 13.

In summary, the embodiment of the disclosure provides a soldering component and a method of assembling the soldering component on objects, which can complete the fastening or unfastening of another object, and achieve the purpose of repeated and quick fastening or unfastening.

The above are only embodiments of the present disclosure, which are not intended to limit the scope of the present disclosure.

What is claimed is:

1. A soldering component, comprising: a body part, the body part has a snap-fit part, and the soldering component has an assembling part for combining to an object.

2. The soldering component according to claim 1, wherein the soldering component is used to be stored in a carrier, and picked up by a tool, after matched with an assembly position of the object by a matching device, the soldering component is placed at the assembly position by the tool for combining to the object.

3. The soldering component according to claim 1, wherein the snap-fit part has an elastic retracting space, and the elastic retracting space can elastically retract two or more fastening parts, so that each fastening part fastens into another object.

4. The soldering component according to claim 1, wherein the snap-fit part has a head and a neck for horizontally fastening to the object.

5. A soldering component, comprising: a body part, an assembling part and a snap-fit part, the soldering component has a solderable surface for soldering to an assembling part of an object, the assembling part of the object is preset with a tin soldering layer, which is heated and soldered the soldering component and the assembling part of the object.

6. The soldering component according to claim 1, wherein there is a supporting part below the snap-fit part of the body part, and the supporting part is used to make the fastened another object stuck.

7. The soldering component according to claim 1, wherein the assembling part of soldering component is set at an assembling part of the object, the assembling part of the object is preset with a tin soldering layer, which is heated and soldered the soldering component and the assembling part of the object.

8. The soldering component according to claim 1, wherein the soldering component has an intermediary, a tool picks up the soldering component by the intermediary, and after the soldering component is matched with an assembly position of the object by a matching device, the soldering component is set at the assembly position.

9. The soldering component according to claim 5, wherein the soldering component has an intermediary, a tool picks up the soldering component by the intermediary, and after the soldering component is matched with an assembly position of the object by a matching device, the soldering component is set at the assembly position.

10. The soldering component according to claim 1, wherein the soldering component has an intermediary, a tool picks up the soldering component by the intermediary to set at an assembly position of the object for conducting a combination, and after the combination is completed, the intermediary is removed.

11. The soldering component according to claim 5, wherein the soldering component has an intermediary, a tool picks up the soldering component by the intermediary to set at an assembly position of the object for conducting a combination, and after the combination is completed, the intermediary is removed.

12. The soldering component according to claim 1, wherein the body part has an anti-rotation part, the anti-rotation part is passed and set in the object, the object has a corresponding anti-rotation part, the anti-rotation part and the corresponding anti-rotation part are anti-rotational mutually.

13. The soldering component according to claim 5, wherein the body part has an anti -rotation part, the anti-rotation part is passed and set in the object, the object has a corresponding anti-rotation part, the anti-rotation part and the corresponding anti-rotation part are anti-rotational mutually.

14. The soldering component according to claim 12, wherein there is a tin soldering layer between the anti-rotation part and the corresponding anti-rotation part, the tin soldering layer is cooled after heating and soldering.

15. The soldering component according to claim 13, wherein there is a tin soldering layer between the anti-rotation part and the corresponding anti-rotation part, the tin soldering layer is cooled after heating and soldering.

16. The soldering component according to claim 1, wherein the body part has a fixedly connecting part, the fixedly connecting part fastens to a corresponding fixedly connecting part, and is used to fixedly connect with each other after the body part is soldered to the object.

17. The soldering component according to claim 5, wherein the body part has a fixedly connecting part, the fixedly connecting part fastens to a corresponding fixedly connecting part, and is used to fixedly connect with each other after the body part is soldered to the object.

18. The soldering component according to claim 1, wherein the body part and the snap-fit part are two independent components combined movably with each other.

19. The soldering component according to claim 18, wherein the body part and the snap-fit part are two independent components combined movably with each other, wherein an elastic component is further included, one end of the elastic component abuts against the body part, and the other end thereof abuts against the snap-fit part, so that the snap-fit part is located at a position where it is put up by the elastic component, or the snap-fit part is located at a position where it is tightly pulled by the elastic component.

20. The soldering component according to claim 5, wherein the body part and the snap-fit part are two independent components combined movably with each other.

21. The soldering component according to claim 1, wherein the assembling part has a stock accommodating space, an assembly position of the object has an opening, and after the stock accommodating space of the assembling part sets in the opening of the object, the assembling part is pressed by an external force, so that the material around the opening flows into or enters the stock accommodating space.

22. The soldering component according to claim 1, wherein the assembling part has an expansion joint, an assembly position of the object has an opening, and after the expansion joint of the assembling part sets in the opening of the object, the expansion joint is pressed by an external force to deform the expansion joint outward for connecting around the opening.

23. The soldering component according to claim 1, wherein the assembling part has a fastening joint, an assembly position of the object has an opening, and after the fastening joint of the assembling part sets in the opening of the object, the fastening joint fastens around the opening.

24. The soldering component according to claim 1, wherein the assembling part has a locking joint, an assembly position of the object has an opening, and after the locking joint of the assembling part sets in the opening of the object, the locking joint locks around the opening.

25. The soldering component according to claim 1, wherein there is a tin soldering layer between an assembling part and the object, the tin soldering layer is for fixedly connecting after cooling.

26. The soldering component according to claim 1, wherein the snap-fit part that is connected movably with the body part is an intermediary.

27. The soldering component according to claim 1, wherein the body part is just an assembly part.

28. The soldering component according to claim 5, wherein the body part is just an assembly part.

29. The soldering component according to claim 2, wherein the tool includes a pickup piece and a moving piece movable relative to the pickup piece, an elastic component is set between the pickup piece and the moving piece, the elastic component is compressed when the moving piece moves relative to the pickup piece.
